(19) United States
(12) Patent Application Publication
(10) Pub. No.: US 2015/0011075 A1
(43) Pub. Date: Jan. 8, 2015

(54) VACUUM DEPOSITION APPARATUS AND METHOD USING THE SAME

(71) Applicant: Samsung Display Co., LTD., Yongin-City (KR)

(72) Inventor: Jeong-Won HAN, Seongnam-si (KR)

(21) Appl. No.: 14/249,111

(22) Filed: Apr. 9, 2014

(30) Foreign Application Priority Data
Jul. 8, 2013 (KR) 10-2013-0079806

(51) Int. Cl. H01L 51/00

(52) U.S. Cl. CPC H01L 51/0002
USPC 438/478; 118/50

(57) ABSTRACT

A vacuum deposition apparatus includes a vacuum deposition device, a mask, a vacuum chamber and a controlling unit. The vacuum deposition device deposits a thin film layer on a substrate. The mask is disposed between the substrate and the vacuum deposition device, and the thin film layer is selectively deposited on the substrate using the mask. The vacuum chamber surrounds the vacuum deposition device and the mask, the controlling unit is disposed outside of the vacuum chamber, and the controlling unit is connected with the vacuum deposition device and controls both a tensile force and a compressive force on the mask.

### CLAIM OF PRIORITY

This application makes reference to, incorporates the same herein, and claims all benefits accruing under 35 U.S.C §119 from an application earlier filed in the Korean Intellectual Property Office on the 8^{th} of July 2013 and there duly assigned Serial No. 10-2013-0079806.

### BACKGROUND OF THE INVENTION

1. Field of the Invention

Example embodiments relate generally to a vacuum deposition apparatus and a method for a vacuum deposition using the same. More particularly, embodiments of the inventive concept relate to a vacuum deposition apparatus which includes a device for controlling a tensile force or a compressive force on a mask to correct a deformation or size of the mask.

2. Description of the Related Art

An organic light emitting element used for an organic light emitting display device is a light emissive type element which has an organic light emitting layer formed between two electrodes. In the organic light emitting display device, electrons and holes are injected into the organic light emitting layer from a electron injection electrode and a hole injection electrode, respectively. The injected electrons and holes are combined to generate excitons, which illuminate when converting from an excited state to a ground state. Since the organic light emitting display device includes the light emissive type element, the organic light emitting display device does not need a separate light source. Also, volume and weight of the organic light emitting display device may be reduced compared with a liquid crystal display device. Accordingly, the organic light emitting display device has been widely used as a flat display device.

In general, the organic light emitting layer of the organic light emitting element includes a plurality of functional layers (e.g., a hole injection layer, a hole transport layer, a light emitting layer, an electron transport layer, an electron injection layer, etc.), and a performance of the organic light emitting display element is improved by a combination and an arrangement of these functional layers.

In order to manufacture the organic light emitting display device using a deposition method, a fine metal mask, which has a same pattern with a thin film layer which is formed on a substrate, is interposed between the substrate and a deposition material. A desired pattern is formed on the substrate by spraying the deposition material to the substrate.

When the fine metal mask becomes large-scaled, an etching error for forming the pattern is increased and a center drooping of the mask is also increased. Further, a deformation of the mask that occurred by a repetition of the process causes a defect of display quality.

In order to prevent the deformation of the mask, the mask is welded with the mask frame. But the mask frame may be deformed because of an elastic restoring force of the mask when the mask is welded to the mask frame. Further, a heat which occurred in the process and a stress which occurred in the aligning process cause an additional deformation of the mask. The mask frame should be replaced when a large deformation of the mask occurs. The replacement of the mask frame causes an increase in manufacturing cost.

Thus, a method for correcting the deformation of mask is required.

### SUMMARY OF THE INVENTION

Some example embodiments provide a vacuum deposition apparatus capable of correcting a deformation of a mask.

Some example embodiments also provide a vacuum deposition method capable of correcting a deformation of a mask.

According to some example embodiments, a vacuum deposition apparatus includes a vacuum deposition device, a mask, a vacuum chamber and a controlling unit. The vacuum deposition deposits a thin film layer on a substrate. The mask is disposed between the substrate and the vacuum deposition device, the thin film layer is selectively deposited on the substrate using the mask. The vacuum chamber surrounds the vacuum deposition device and the mask. The controlling unit is disposed outside of the vacuum chamber, and the controlling unit is connected with the vacuum deposition device and controls a tensile force on the mask.

In example embodiments, the vacuum deposition device may include a mask frame, a mask stage, a motor unit and a deposition source. The mask frame has an opening, and the mask frame is welded with the mask. The mask stage supports the mask frame. The motor unit transports the mask stage in a direction away from, or towards, the motor unit. The deposition source sprays a deposition material on the substrate.

In example embodiments, the mask frame may have the opening on the center of the mask frame, and the mask may be welded on the mask frame.

In example embodiments, the mask stage may be disposed on at least one of four sides of the mask frame, and each mask stage may comprise a transporting device which transports the mask stage along the mask frame.

In example embodiments, the vacuum deposition apparatus further comprises a screw inserting hole. The screw inserting hole is disposed in the mask stage.

In example embodiments, the motor unit may comprise a screw, a motor and a dustproof unit. The screw may be inserted into the screw inserting hole of the mask stage, and the screw is rotated in the screw inserting hole. The motor may control a rotation of the screw. The dustproof unit may eliminate a dust which is in the vacuum chamber.

In example embodiments, the screw may comprise at least one selected from the group consisting of a triangular thread, a four-corner screw, a trapezoidal thread and a round thread.

In example embodiments, the screw may be inserted into the screw inserting hole and the mask stage may be transported in a direction away from, or towards, the motor unit by a rotation of the screw.

In example embodiments, the motor may be connected with the controlling unit which is disposed outside of the vacuum chamber and the rotation of the screw may be controlled by the motor.

In example embodiments, the dustproof unit may support the motor.

In example embodiments, the deposition source may store the deposition material which is deposited on the substrate and the deposition source may be disposed under the mask.

According to an aspect of another embodiment, a method of vacuum depositing is provided as follows. A mask is combined with a mask frame which has an opening. A size of the mask is controlled using a controlling unit which is disposed outside of the vacuum chamber. A substrate is disposed on the mask. A thin film layer is deposited on the substrate by spraying a depositing material on the substrate through the mask.

In example embodiments, the mask may comprise a fine metal mask.

In example embodiments, the mask may be disposed on the mask frame and the mask may be welded with the mask frame.

In example embodiments, the controlling unit may be connected with a motor unit which controls the size of the mask frame, and the size of the mask may be controlled by a rotation of a motor of the motor unit.

In example embodiments, the mask may by pulled in an exterior direction of the mask frame when the motor is rotated in the first direction.

In example embodiments, the mask may contract in an interior direction of the mask frame when the motor is rotated in the second direction.

In example embodiments, the substrate may be aligned with the mask.

In example embodiments, the depositing material stored in a deposition source which is disposed under the mask may be sprayed onto the substrate through the mask, and the thin film layer may be deposited on the substrate along a pattern of the mask.

Therefore, a vacuum deposition apparatus may include a mask stage and a mask frame which controls a tensile force to the mask. The mask stage is transported in a direction away from, or towards, a motor unit and a size of the mask may be minutely controlled by the mask stage and the mask frame. Further, a deformation of the mask may be corrected and a replacing period of the mask may be delayed. Thus, a processing cost and a material cost are minimized.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a plane view illustrating a mask;

FIG. 2 is a plane view illustrating a substrate;

FIG. 3 is a cross-sectional view illustrating a vacuum deposition apparatus according to example embodiments;

FIG. 4 is a plane view illustrating a deposition apparatus illustrated in FIG. 3;

FIG. 5 is a cross-sectional view illustrating cross section (A-A′) of a vacuum deposition apparatus illustrated in FIG. 4;

FIG. 6 is a flowchart illustrating a method for vacuum deposition according to example embodiments:

FIGS. 7 and 8 are drawings illustrating an example of a method for vacuum deposition illustrated in FIG. 6;

FIG. 9 is a drawing illustrating an example of an arrangement of a mask stage of a vacuum deposition apparatus illustrated in FIG. 1; and

FIG. 10 is a drawing illustrating another example of an arrangement of a mask stage of a vacuum deposition apparatus illustrated in FIG. 1.

### DETAILED DESCRIPTION OF THE INVENTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

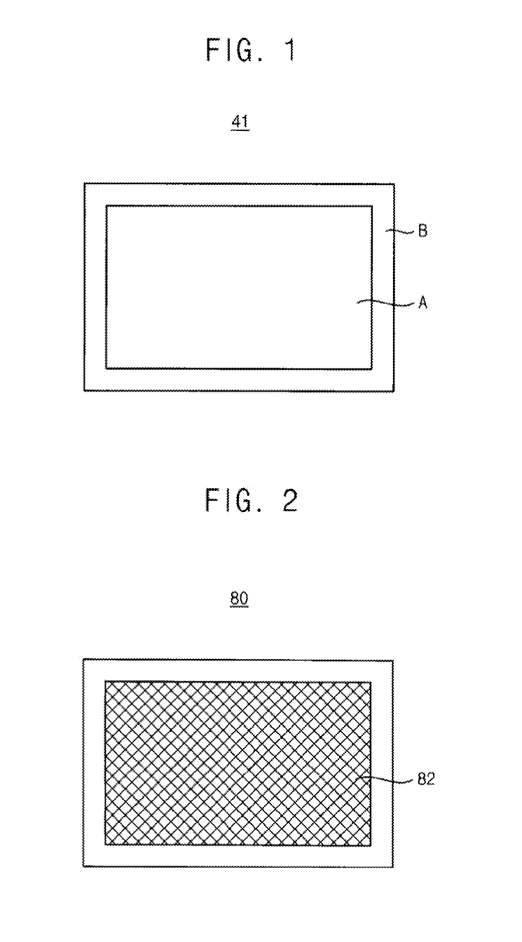

FIG. 1 is a plane view illustrating a mask and FIG. 2 is a plane view illustrating a substrate.

Referring to FIG. 1, a mask 41 has a pattern opening to form a pattern on a substrate. An area that has the pattern opening is an effective area ‘A’ and an area that surrounds the effective area ‘A’ is an ineffective area B. The ineffective area B may be welded with a mask frame which will be described below.

Referring to FIG. 2, a thin film layer 82 may be formed on a center of the substrate 80. The thin film layer 82 which has desired pattern may be formed on the substrate 80 by spraying a deposition material to the substrate 80 through the mask 41.

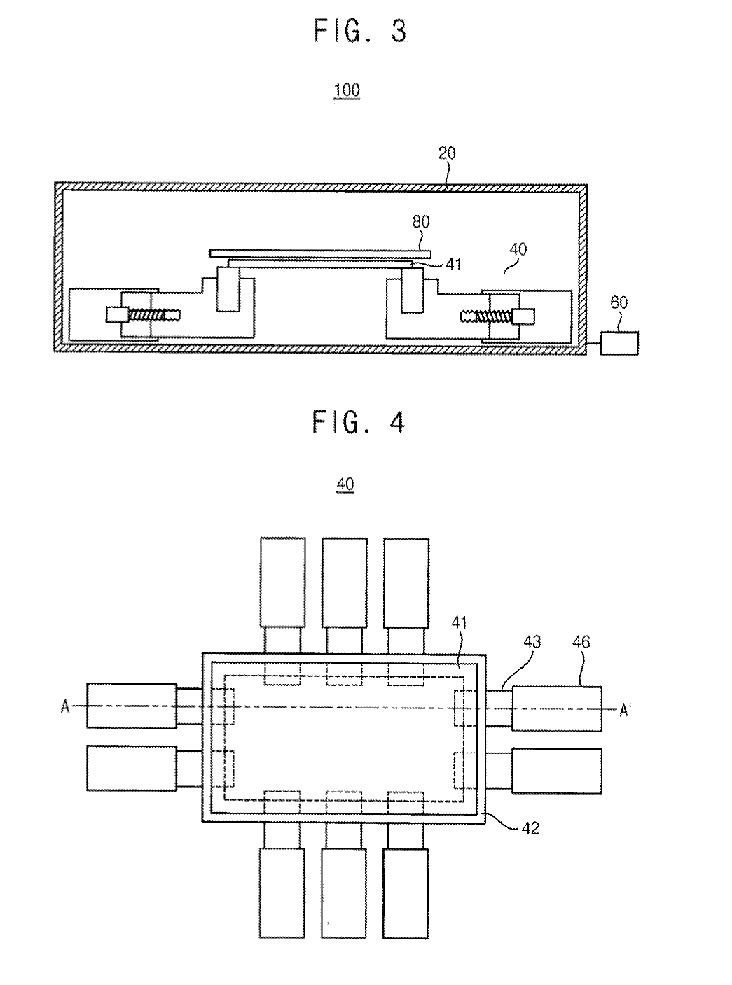

FIG. 3 is a cross-sectional view illustrating a vacuum deposition apparatus according to example embodiments.

Referring to FIG. 3, a vacuum deposition apparatus 100 includes a vacuum chamber 20, a vacuum deposition device 40, a mask 41 and a controlling unit 60.

The vacuum chamber 20 is formed in cylinder-shape or box-shape, and provides a space for forming the thin film layer on the substrate 80. Although the vacuum chamber 20 is box-shape illustrated in FIG. 3, a shape of the vacuum chamber 20 is not limited. It is desired that the vacuum chamber 20 has a various shape corresponding with a shape of the substrate 80.

A vacuum pump (not shown) may be disposed on a top side of the vacuum chamber 20 to maintain a vacuum state and a door (not shown) may be disposed on a side of the vacuum chamber 20 to take in or to take out the substrate 80 for the process.

The vacuum deposition device 40 is disposed in the vacuum deposition chamber 20, and the vacuum deposition device 40 forms the thin film layer on the substrate by spraying the deposition material through the mask 41. Although a deformation of the mask 41 occurred, a size of the mask 41 may be controlled by a device which applies a tensile or a compressive force to the mask.

The controlling unit 60 is disposed outside of the vacuum chamber 20, and the tensile force on the mask 41 is controlled by the controlling unit 60.

A camera (not shown) may be disposed in the vacuum chamber 20 to measure the size of the mask 41. The user may monitor an image which is taken from the camera, and may control the size of the mask 41 using the controlling unit 60. The size of the mask 41 may be monitored by a distance measuring sensor (not shown). The device to measure the size of mask 41 is not limited.

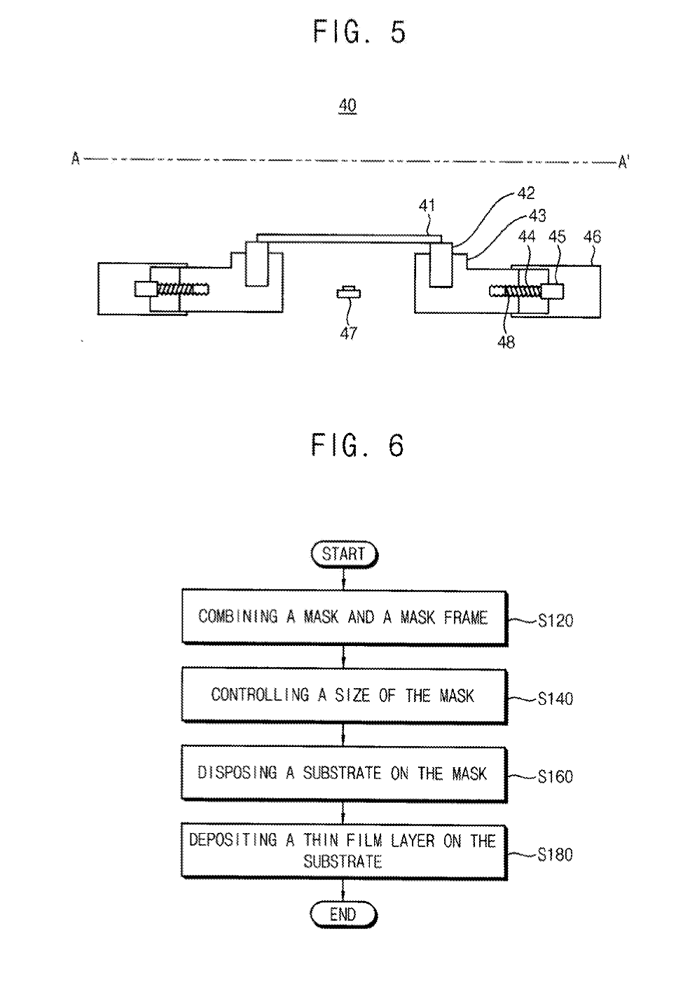

FIG. 4 is a plane view illustrating a deposition apparatus illustrated in FIG. 3 and FIG. 5 is a cross-sectional view illustrating cross section (A-A′) of a vacuum deposition apparatus illustrated in FIG. 4.

Referring to FIGS. 4 and 5, the vacuum deposition device 40 includes the mask 41, the mask frame 42, the mask stage 43, the motor unit 44, 45 and 46 and the deposition source 47.

As illustrated in FIGS. 1 and 5, the mask 41 has the effective area A and the ineffective area B, and the ineffective area B is welded on the mask frame 42.

The mask frame 42 is a frame shape which has an opening. The effective area A of the mask 41 is aligned with the opening of the mask frame 42, and the mask 41 is disposed on the mask frame 42. The mask frame 42 is welded with the ineffective area B of the mask 41. The mask frame 42 which welded with the mask 41 applies the tensile force or compressive force to the mask 41 by moving in a direction away from, or towards, the motor unit 44, 45 and 46. The mask frame 42 may be formed of a material which is not deformed in a welding process, for example, strong property metal.

The mask stage 43 has a concave (channel) portion in which the mask frame 42 is positioned, the mask stage 43 being disposed on at least one of four sides of the mask frame and is transported along the mask frame 42 with a transporting device (not shown). A method and an apparatus which transports the mask stage 43 along the mask frame 42 are various. The mask stage 43 may apply the tensile force or compressive force to any desired position of the mask frame 42 by being transported along the mask frame 42. Further, the mask stage 43 may minutely control a range on which the tensile or compressive forces act by changing a size of the mask stage 43.

The motor unit includes a screw 44, a motor 45 and a dustproof unit 46.

The screw 44 may be inserted into a screw inserting hole 48 of the mask stage 43, and the screw 44 may transport the mask stage 43 in the direction away from, or towards, the motor 45 by a rotation of the screw 44. The screw 44 includes at least one selected from the group consisting of a triangular thread, a four-corner screw, a trapezoidal thread and a round thread.

The motor 45 may rotate the screw 44. The motor 45 is connected with the controlling unit 60 which is disposed outside of the vacuum chamber 20. The motor 45 is controlled outside of the vacuum chamber 20 by monitoring the size of mask 41 using the camera (not shown) which is disposed in the vacuum chamber 20.

The dustproof unit 46 may be disposed at the end of the motor 45 and may support the motor 45. Further, the dustproof unit 46 may eliminate fine impurities in the vacuum chamber 20. The dustproof unit 46 may be tightly fixed on the vacuum chamber to support against forces which push or pull the mask stage 43. When the substrate 80 is entered into the vacuum chamber 20, impurities may be entered with the substrate 80, and when the mask stage 43 is moved, impurities may occur. By eliminating impurities, the dustproof unit 46 decreases a defect which occurred by impurities. A method or a device for eliminating the impurities is various.

The deposition source 47 may be a crucible and may store the deposition material which may be deposited on the substrate 80. And the deposition source 47 sprays the deposition material to form the desired thin film layer on the substrate 80.

FIG. 6 is a flowchart illustrating a method for vacuum deposition according to example embodiments.

Referring to FIG. 6, the mask is welded on the mask frame S120. As described, the mask is disposed on the mask frame, and the effective area of the mask is aligned with the opening of the mask frame. And the ineffective area of the mask is welded with the mask frame.

The size of the mask is controlled S140. When the mask which is welded with the mask frame is deformed, the mask and the mask frame may be discarded together. Alternately, when a tensile force or compressive force acts on the mask using the mask frame, the deformation of the mask may be corrected. Thus, a material cost which is for manufacturing a new mask and a new mask frame and a processing cost which is for welding the new mask and the new mask frame may be decreased.

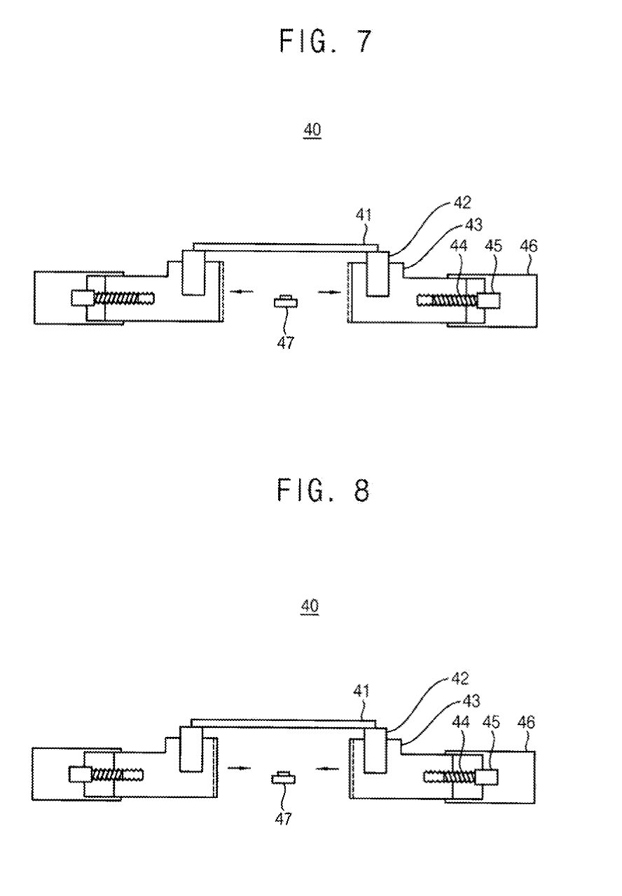

The size of the mask may be controlled by the controlling unit. In specific, the mask stage may be transported to the position which needs to control the size of the mask using the controlling unit which is disposed outside of the vacuum chamber. The motor which is connected with the mask stage is operated. The screw which is connected with the motor and which is inserted into the mask stage is rotated in a first direction or a second direction which is opposite to the first direction. According to the rotation direction of the screw, the mask stage is transported in the direction away from, or towards, (exterior direction (←→) or interior direction (→←) as shown in FIGS. 7 and 8) of the mask frame. The mask frame may be pulled or pushed according to the moving direction of the mask stage because the mask stage supports the mask frame and the mask frame is attached to the mask stage. The size of the mask may be corrected by applying a tensile (tension or stretching) force or compressive force to the mask using the mask frame.

When a center drooping of the mask has occurred in a large-sealed mask due to a repetition of the vacuum deposition process, the screw which is connected with the motor may be rotated in the first direction using the controlling unit. The mask stage may be pulled towards the motor, which is an exterior direction (←→) of the mask frame, the mask frame also being pulled to the exterior direction of the mask frame. The mask, which is welded with the mask frame, will also be pulled in the exterior direction of the mask frame. Thus, the center drooping of the mask is corrected. When the tensile force applied excessively to the exterior direction of the mask frame, the screw may be rotated in the second direction using the controlling unit, thus the tensile force which is applied to the mask is relaxed.

As described, the mask stage may be transported along the mask frame, and may minutely control the range on which the tensile force or compressive force acts by changing the size of the mask stage.

The substrate is disposed on the mask S160. The substrate may be aligned with the mask of which size is controlled. The substrate is disposed on the mask without a gap or with a gap which is maintained by a gap controlling member.

A thin film layer may be deposited on the substrate S180. The deposition material which stored in the deposition source that is disposed under the mask may be sprayed to the opening of the mask. The thin film layer of which pattern is the same with the pattern of the mask may be deposited on the substrate.

FIGS. 7 and 8 are drawings illustrating an example of a method for vacuum deposition illustrated in FIG. 6.

Referring to FIG. 7, when the screw 44 is rotated in the first direction by the motor 45, the mask stage 43 is transported in the exterior direction (←→) of the mask frame 42. The first direction may be a clockwise rotation. The tensile force is applied to the mask frame 42 which is supported by the mask stage 43 to the exterior direction (←→) of the mask frame 42. The mask 41 which is welded on the mask frame 42 is pulled in the exterior direction (←→) of the mask frame 42. Thus, if a center drooping of the mask 42 has occurred, the size of the mask 41 is corrected by the screw 44 which is rotated in the first direction.

Referring to FIG. 8, when the screw 44 is rotated in the second direction which is opposite to the first direction by the motor 45, the mask stage 43 is transported in the interior direction (→←) of the mask frame 42. The second direction may be an anticlockwise direction. The compressive force is applied to the mask frame 42 which is supported by the mask stage 43 to the interior direction (→←) of the mask frame 42. The mask 41 which is welded on the mask frame 42 is contracted to the interior direction (→←) of the mask frame 42. Thus, if stretching of the mask 42 has occurred by the heat and the stress in the vacuum deposition process, the size of the mask 41 is corrected by the screw 44 which is rotated in the second direction.

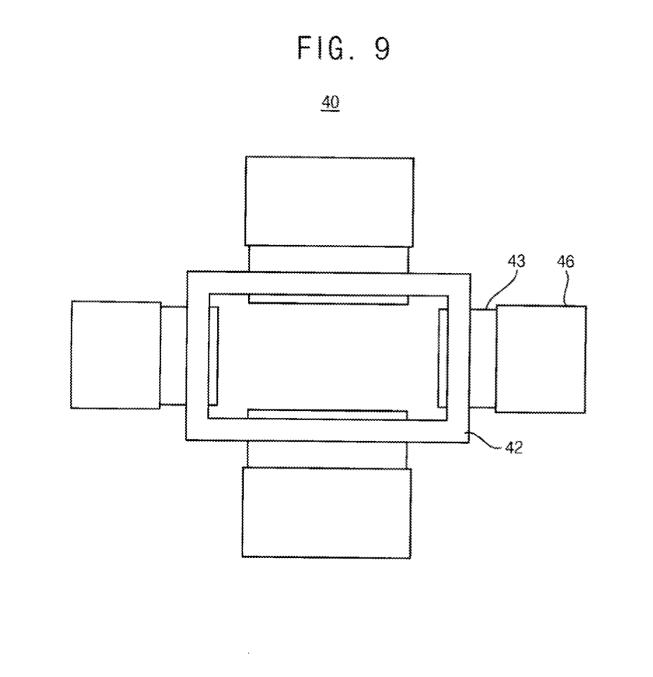

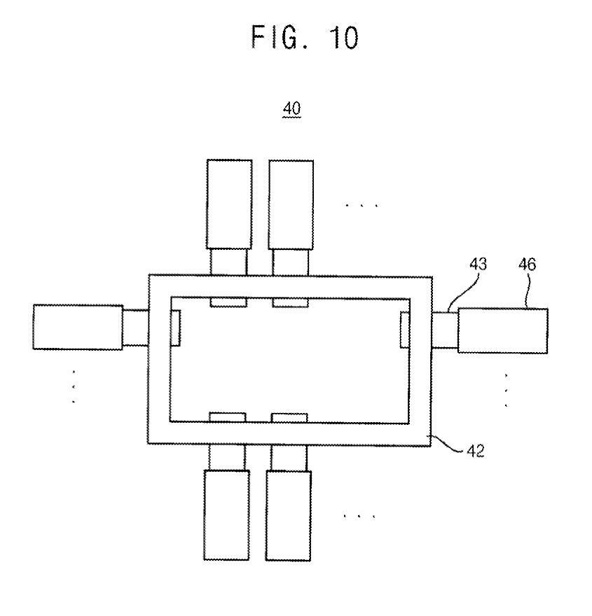

FIG. 9 is a drawing illustrating an example of an arrangement of a mask stage of a vacuum deposition apparatus illustrated in FIG. 3; and FIG. 10 is a drawing illustrating another example of an arrangement of a mask stage of a vacuum deposition apparatus illustrated in FIG. 3.

Referring to FIGS. 9 and 10, the mask stage 43 is disposed on at least one of four sides of the mask frame 42.

As illustrated in FIG. 9, one mask stage 43 is disposed on each of four sides of the mask frame 42. A length of the mask stage 43 may be the same with a length of the mask frame 42. When the screw which is inserted in the mask stage 43 is rotated, the same tensile or compressive force may be applied to one or more sides of the mask frame 43.

As illustrated in FIG. 10, a plurality of mask stages 43 are disposed on each of four sides of the mask frame 42. When the size of the mask stage 43 is small, the size of the mask may be minutely controlled. In specific, because the small size of the mask stage 43 includes a transporting device (not shown) to move in a desired direction with respect to the mask frame 42, any area of the mask in which deformation may have occurred may be minutely corrected. Further, a different tensile or compressive force may be applied to the mask frame 43.

The number and the size of the mask stages 43 may be decided considering a property of the mask 41 and a cost of the facility. Additionally, each mask stage 43 can be controlled individually or as groups, to move in a desired direction.

The vacuum deposition apparatus includes the mask stage and mask frame which applies a tensile or compressive, force to the mask, the deformation of the mask may be corrected and the replacing period of the mask may be delayed. Thus, the material cost and the processing cost may be decreased.

The present invention concept may be applied to any deposition process using a mask. For example, the present inventive concept may be applied to a manufacturing method of semiconductor elements and display device that includes the deposition process using the mask.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A vacuum deposition apparatus comprising:
a vacuum deposition device depositing a thin film layer on a substrate;
a mask disposed between the substrate and the vacuum deposition device, the thin film layer being selectively deposited on the substrate using the mask;
a vacuum chamber surrounding the vacuum deposition device and the mask; and
a controlling unit disposed outside of the vacuum chamber, the controlling unit connected with the vacuum deposition device and controlling both a tensile force and a compressive force on the mask.

2. The vacuum deposition apparatus of claim 1, the vacuum deposition device comprising:
a mask frame having an opening, the mask frame being welded with the mask;
a mask stage supporting the mask frame;
a motor unit transporting, at different times, the mask stage in a direction away from and towards the motor unit; and
a deposition source spraying a deposition material on the substrate.

3. The vacuum deposition apparatus of claim 2, the mask frame having the opening centrally disposed in the mask frame, the mask being welded on the mask frame.

4. The vacuum deposition apparatus of claim 2, the mask stage being disposed on at least one of four sides of the mask frame, and each mask stage comprises a transporting device which transports the mask stage along the mask frame.

5. The vacuum deposition apparatus of claim 2, further comprising:
a screw inserting hole disposed in the mask stage.

6. The vacuum deposition apparatus of claim 5, the motor unit comprising:
a screw inserted into the screw inserting hole of the mask stage, the screw being rotated in the screw inserting hole;
a motor controlling a rotation of the screw; and
a dustproof unit eliminating a dust which is in the vacuum chamber.

7. The vacuum deposition apparatus of claim 6, wherein the screw comprises at least one selected from the group consisting of a triangular thread, a four-corner screw, a trapezoidal thread and a round thread.

8. The vacuum deposition apparatus of claim 6, the screw being inserted into the screw inserting hole and the mask stage being transported in direction away from, or towards, the motor by a rotation of the screw.

9. The vacuum deposition apparatus of claim 6, the motor being connected with the controlling unit, which is disposed outside of the vacuum chamber, and the rotation of the screw is controlled by the motor.

10. The vacuum deposition apparatus of claim 6, the dustproof unit supporting the motor.

11. The vacuum deposition apparatus of claim 2, the deposition source storing the deposition material which is to be deposited on the substrate, the deposition source being disposed under the mask.

12. A method for vacuum deposition, the method comprising:
combining a mask with a mask frame which has an opening;
controlling a size of the mask using a controlling unit which is disposed outside of the vacuum chamber, the controlling unit controlling both a tensile force and a compressive force on the mask;
disposing a substrate on the mask; and
depositing a thin film layer on the substrate by spraying a depositing material on the substrate through the mask.

13. The method of claim 12, the mask comprising a fine metal mask.

14. The method of claim 12, the mask being disposed on the mask frame and the mask being welded with the mask frame.

15. The method of claim 12, wherein:
the controlling unit is connected with a motor unit which controls the size of the mask frame, and
the size of the mask is controlled by a rotation of a motor of the motor unit.

16. The method of claim 15, wherein the mask expands to an exterior direction of the mask frame when the motor is rotated in a first direction.

17. The method of claim 15, wherein the mask contracts to an interior direction of the mask frame when the motor is rotated in a second direction which is opposite to the first direction.

18. The method of claim 12, the substrate being aligned with the mask.

19. The method of claim 12, the depositing material stored in a deposition source, which is disposed under the mask, being sprayed onto the substrate through the mask, the thin film layer being deposited on the substrate according to a pattern of the mask.
